(19) United States
(12) Patent Application Publication
(10) Pub. No.: US 2018/0231830 A1
(43) Pub. Date: Aug. 16, 2018

(54) ARRAY SUBSTRATE AND METHOD OF MANUFACTURING THE SAME, AND DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Jun Wu, Beijing (CN); Qing Miao, Beijing (CN)

(21) Appl. No.: 15/513,552

(22) PCT Filed: Sep. 5, 2016
(86) PCT No.: PCT/CN2016/097993

§ 371 Date: Mar. 22, 2017

(30) Foreign Application Priority Data
Jan. 11, 2016 (CN) 201610015484.6

(51) Int. Cl. G02F 1/1335; H01L 27/12

(52) U.S. Cl. CPC G02F 1/133516; G02F 2201/52; H01L 27/12; G02F 1/133603

(57) ABSTRACT

The present disclosure provides an array substrate and a method of manufacturing the same, and a display device. The array substrate includes a red light emitting unit, a green light emitting unit and a blue light emitting unit; the red light emitting unit includes a red phosphor layer configured for emitting red light under excitation of blue light emitted from a light source; the green light emitting unit includes a green phosphor layer configured for emitting green light under excitation of the blue light emitted from a light source; and the blue light emitting unit is configured for, when being irradiated by the blue light emitted from a light source, emitting blue light.

### CROSS-REFERENCE TO RELATED APPLICATION

This application is a Section 371 National Stage Application of International Application No. PCT/CN2016/097993, filed on Sep. 5, 2016, entitled “ARRAY SUBSTRATE AND METHOD OF MANUFACTURING THE SAME, AND DISPLAY DEVICE”, which has not yet published and which claims priority to Chinese Application No. 201610015484.6, filed on Jan. 11, 2016, incorporated herein by reference in their entirety.

### BACKGROUND

### Technical Field

The present disclosure pertains to the field of display technologies, and particularly, to an array substrate and a method of manufacturing the same, and a display device.

### Description of the Related Art

Thin Film Transistor Liquid Crystal Display (TFT-LCD for short), which has characteristics such as a small volume, low power consumption, no radiation and the like, has been developed rapidly in recent years and currently has become predominant in the market of flat panel displays.

As shown in FIG. 1, a liquid crystal display comprises a display module (which comprises an array substrate 1A, a color filter substrate 2, and a liquid crystal layer 3) and a backlight module 4A for providing backlight to the display module. The backlight module utilizes a while light LED as a light source. The while light LED is obtained by adding yellow phosphor on basis of a blue light LED, and thus, is also called as 1-PCLED (Phosphor Converted LED). Such LED is packaged by using an epoxy resin, thus light can be easily emitted out from such LED. A major constituent of the used phosphor is YAG:Ce, which has a chemical formula of (Y1-aGda)₃(Al1-bGab)O₁₂:Ce³⁺. Gd (Gadolinium) may change Ce³⁺'s crystal field, such that wavelength of light is increased and thereby yellow light is emitted, and this yellow light is mixed with blue light so as to form white light.

The inventors have found that there are at least following problems in prior arts: as described above, with the yellow light mixing with the blue light to form the white light, green and blue light components of the white light will be filtered out after the white light is irradiated onto a red filter of the color filter substrate and only a red light component of the white light is allowed to be transmitted through the red filter; red and blue light components of the white light will be filtered out after the white light is irradiated onto a green filter and only a green light component of the white light is allowed to be transmitted through the green filter; and red and green light components of the white light will be filtered out after the white light is irradiated onto a blue filter and only a blue light component of the white light is allowed to be transmitted through the blue filter. This phenomenon results in a lower utilization rate of the light source.

### SUMMARY

In order to solve the above and other problems and defects in existing liquid crystal displays, an object of the present disclosure is to at least provide an array substrate and a method of manufacturing the same, and a display device, enabling a high utilization rate of a light source.

An embodiment of the present disclosure provides an array substrate comprising a red light emitting unit, a green light emitting unit and a blue light emitting unit, the red light emitting unit comprises a red phosphor layer configured for emitting red light under excitation of blue light emitted from a light source, the green light emitting unit comprises a green phosphor layer configured for emitting green light under excitation of the blue light emitted from the light source, and the blue light emitting unit is configured for, when being irradiated by the blue light emitted from the light source, emitting blue light.

In one embodiment, the blue light emitting unit comprises a blue phosphor layer configured for, under excitation of the blue light emitted from the light source, emitting blue light.

In one embodiment, a material of the blue phosphor layer is BaMgAl₁₄O₂₃:Ru.

In one embodiment, the blue light emitting unit is configured to transmit the blue light emitted from the light source therethrough.

In one embodiment, the red light emitting unit, the green light emitting unit and the blue light emitting unit are provided on a light incidence side of the array substrate.

In one embodiment, the red light emitting unit, the green light emitting unit and the blue light emitting unit are provided on a light emergence side of the array substrate.

In one embodiment, the array substrate further comprises a color filter layer, and the color filter layer is arranged on light emergence sides of the red light emitting unit, the green light emitting unit and the blue light emitting unit.

In one embodiment, a material of the red phosphor layer is Y₂O₃:Ru, and a material of the green phosphor layer is SrGa₂S₄:Ru.

In one embodiment, the red light emitted by the red light emitting unit under excitation of the blue light has a wavelength of 700±50 nm, the green light emitted by the green light emitting unit under excitation of the blue light has a wavelength of 546±50 nm, and the blue light emitted by the blue light emitting unit when being irradiated by the blue light has a wavelength of 435±50 nm.

An embodiment of the present disclosure further provides a method of manufacturing an array substrate, the array substrate comprises a red light emitting unit, a green light emitting unit and a blue light emitting unit, the blue light emitting unit being configured to, when being irradiated by blue light emitted from a light source, emit blue light, and the method comprises steps of: forming a red phosphor layer in the red light emitting unit, the red phosphor layer being configured for emitting red light under excitation of the blue light emitted from the light source; and forming a green phosphor layer in the green light emitting unit, the green phosphor layer being configured for emitting green light under excitation of the blue light emitted from the light source.

In one embodiment, the method further comprises a step of: forming a blue phosphor layer in the blue light emitting unit, the blue phosphor layer being configured for, under excitation of the blue light emitted from the light source, emitting blue light.

In one embodiment, the method further comprises a step of: forming a color filter layer on light emergence sides of the red light emitting unit, the green light emitting unit and the blue light emitting unit.

In one embodiment, the step of forming a color filter layer comprises forming a red filter, a green filter and a blue filter, and a mask used to form the red filter, the green filter and the blue filter is the same as a mask used to form the red phosphor layer, the green phosphor layer and the blue phosphor layer.

An embodiment of the present disclosure further provides a display device comprising the above array substrate.

### BRIEF DESCRIPTION OF THE DRAWINGS

FIG. 1 is a structural schematic diagram of an existing liquid crystal display.

FIG. 2 is a structural schematic diagram of an array substrate according to an embodiment of the present disclosure.

FIG. 3 is another structural schematic diagram of the array substrate according to another embodiment of the present disclosure.

FIG. 4 is a structural schematic diagram of a display device according to an embodiment of the present disclosure.

FIG. 5 is a schematic diagram showing spectrums obtained after blue light is irradiated onto a red phosphor layer, a green phosphor layer and a blue phosphor layer according to an embodiment of the present disclosure.

FIG. 6 is a spectrogram of white light, which is obtained by mixing spectrums of three colors shown in FIG. 5, under different currents.

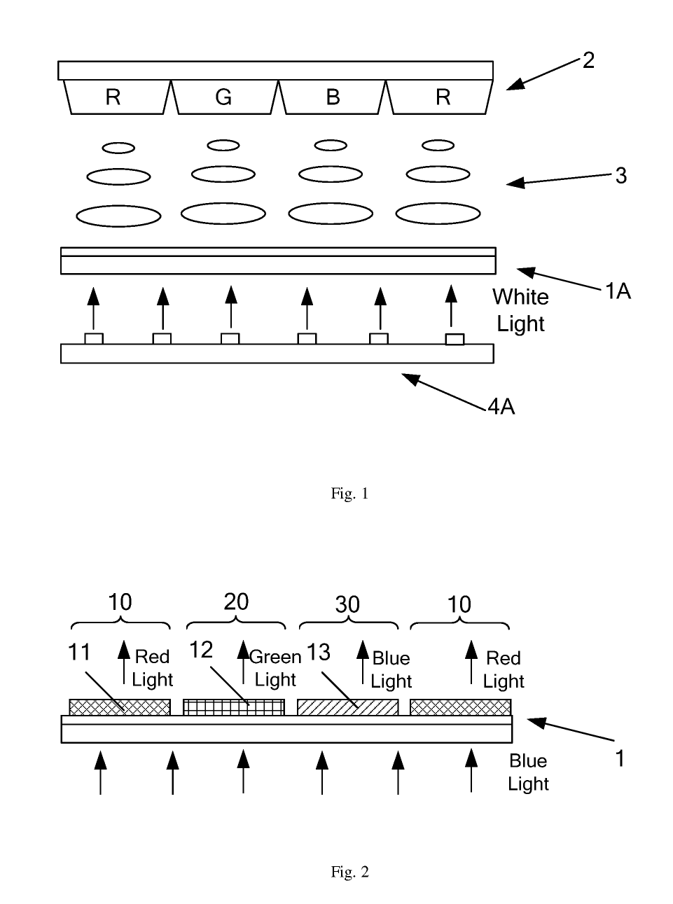

### DETAILED DESCRIPTION OF PREFERRED EMBODIMENTS

In order that those skilled in the art could understand schemes of the present disclosure in a better way, the present disclosure will be further described in detail with reference to the drawings and exemplary embodiments.

In addition, in the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

As shown in FIG. 2 to FIG. 4, an embodiment of the present disclosure provides an array substrate 1 comprising a red light emitting unit 10, a green light emitting unit 20 and a blue light emitting unit 30. The red light emitting unit 10 comprises a red phosphor layer 11 configured for emitting red light under excitation of blue light emitted from a light source. The green light emitting unit comprises a green phosphor layer 12 configured for emitting green light under excitation of the blue light emitted from the light source. The blue light emitting unit is configured for, when being irradiated by blue light emitted from the light source, emitting blue light.

Exemplarily, as shown in FIG. 4, a display device generally comprises an array substrate 1 and an opposite substrate 2 arranged opposite to each other (with a liquid crystal layer 3 arranged therebetween), and a backlight module 4. Generally, a display panel comprises sub-pixels of red, green and blue colors, and correspondingly, the array substrate 1, as an important part of the display panel, comprises a red light emitting unit, a green light emitting unit and a blue light emitting unit. In the embodiment, the red light emitting unit of the array substrate 1 comprises the red phosphor layer 11, and the green light emitting unit comprises the green phosphor layer 12. Thus, in case that the backlight module 4 utilizes a blue backlight module 4, when blue light emitted from the backlight module 4 is irradiated onto the red phosphor layer 11, the red phosphor layer 11 will be excited to emit red light; when the blue light is irradiated onto the green phosphor layer 12, the green phosphor layer 12 will be excited to emit green light; when the blue light is irradiated onto the blue light emitting unit, the blue light emitting unit may emit blue light. Then, all of the red light may be substantially transmitted through a corresponding red filter (denoted by symbol “R” shown in FIG. 4) when irradiating the red filter, all of the green light may be substantially transmitted through a corresponding green filter (denoted by symbol “G” shown in FIG. 4) when irradiating the green filter, and all of the blue light may be substantially transmitted through a corresponding blue filter (denoted by symbol “B” shown in FIG. 4) when irradiating the blue filter. Finally, the light of red, green and blue colors that have been transmitted through color filters of corresponding colors are mixed with each other so as to achieve color display. Further, as can be seen, substantially, there is no too much loss in light irradiating the color filters, that is, the array substrate according to embodiments of the present disclosure can improve utilization rate of the light source. In prior arts, however, a white light source is obtained by coating yellow phosphors directly on a blue light chip of the backlight module 4. Thereafter, green and blue light components of the white light will be filtered out when the white light passes through a red filter (that is, in prior arts, the green and blue light components of the white light are lost when the white light passes through the red filter) and only a red light component of the white light is allowed to be transmitted through the red filter; red and blue light components of the white light will be filtered out after the white light passes through a green filter (that is, in prior arts, the red and blue light components of the white light are lost when the white light passes through the green filter) and only a green light component of the white light is allowed to be transmitted through the green filter; and red and green light components of the white light will be filtered out after the white light passes through a blue filter (that is, in prior arts, the red and green light components of the white light are lost when the white light passes through the blue filter) and only a blue light component of the white light is allowed to be transmitted through the blue filter. As can be seen from above, transmittance and utilization rate of the light source in embodiments of the present disclosure are greater than those in prior arts.

As an implementation of an embodiment of the present disclosure, a blue phosphor layer 13 is provided in the blue light emitting unit of the array substrate 1, and blue light which is irradiated onto the blue phosphor layer 13 can excite the blue phosphor layer 13 to emit blue light, as shown in FIG. 2.

In an embodiment of the present disclosure, a material of the blue phosphor layer 13 is BaMgAl₁₄O₂₃:Ru, a material of the red phosphor layer 11 is Y₂O₃:Ru, and a material of the green phosphor layer 12 is SrGa₂S₄:Ru.

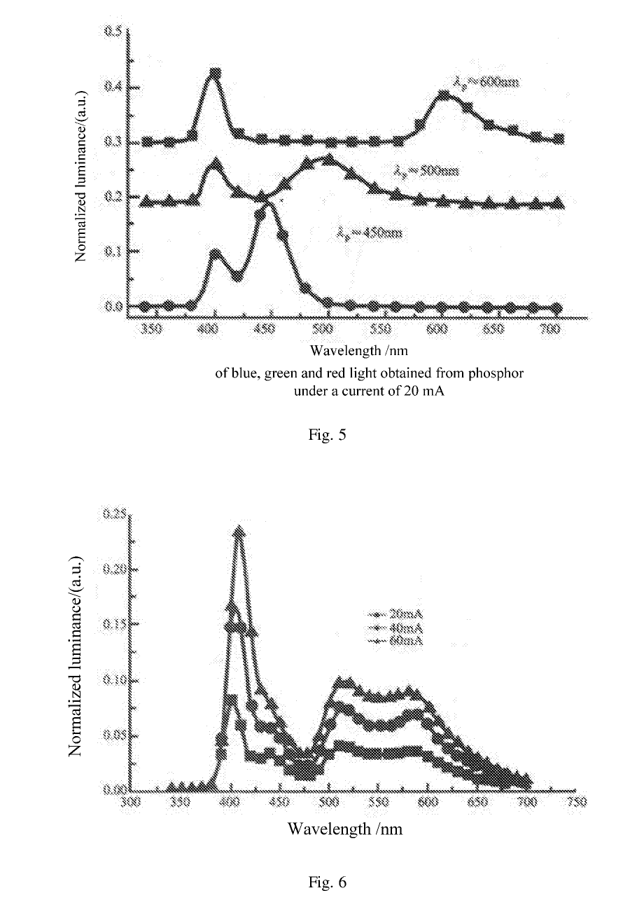

Exemplarily, in case the material of the blue phosphor layer 13 is BaMgAl₁₄O₂₃:Ru, the material of the red phosphor layer 11 is Y₂O₃:Ru, and the material of the green phosphor layer 12 is SrGa₂S₄:Ru, spectrums of light, which is generated under excitation by using light emitted from the blue backlight source, that is, from the blue light emitting chip, under excitation of a current of 20 mA, to irradiate the red phosphor layer 11, the green phosphor layer 12, the blue phosphor layer 13, are shown in FIG. 5 and FIG. 6. In an example, a wavelength λₚ of an excitation spectrum generated by irradiating the red phosphor layer 11 with light emitted from the blue backlight source is 600 nm, a wavelength λp of an excitation spectrum generated by irradiating the green phosphor layer 12 with light emitted from the blue backlight source is 500 nm, and a wavelength λp of an excitation spectrum generated by irradiating the blue phosphor layer 13 with light emitted from the blue backlight source is 450 nm. FIG. 6 is a spectrogram of white light, which is obtained by mixing light of three colors shown in FIG. 5, where three graphs respectively represent excitation spectrums generated by the blue light emitting chip as the backlight source under currents of 20 mA, 40 mA and 60 mA. When the current is 20 mA, a final luminous efficiency of the white light is 101 m/W. Thereby, it will not be difficult to understand that a light output efficiency of the display panel can be effectively improved by using the structure of the array substrate in this embodiment. Of course, in embodiments of the present disclosure, the materials of the red phosphor layer 11, the green phosphor layer 12 and the blue phosphor layer 13 are not limited to those described above, and other materials may be utilized as required.

Further, in prior arts, wavelengths of red light, blue light and green light obtained by coating a yellow phosphor layer on the blue light emitting chip are 630 nm, 490 nm and 380 nm respectively. Experiment results show that in an embodiment of the present disclosure, the wavelength of the red light emitted by the red phosphor layer 11 when being excited by blue light is 700±50 nm (that is, in a range from 650 nm to 750 nm); the wavelength of the green light emitted by the green phosphor layer 12 when being excited by blue light is 546±50 nm (that is, in a range from 496 nm to 596 nm); and the wavelength of the blue light emitted by the blue phosphor layer 13 when being excited by blue light is 435±50 nm (that is, in a range from 385 nm to 485 nm). These wavelengths of the light of three colors and wavelengths of light of three colors obtained in prior arts are mapped to a color gamut diagram such that their chromaticity coordinates can be acquired. Further, it can be seen that, as compared to the chromaticity coordinates of the red light, blue light, green light obtained in prior arts by coating the yellow phosphor layer on the blue light emitting chip, the chromaticity coordinates of the red light, blue light, green light obtained in embodiments of the present disclosure are closer to pure colors. That is, the red light, blue light, green light obtained in embodiments of the present disclosure have wider color gamut and higher purities, and thus a better display effect is achieved.

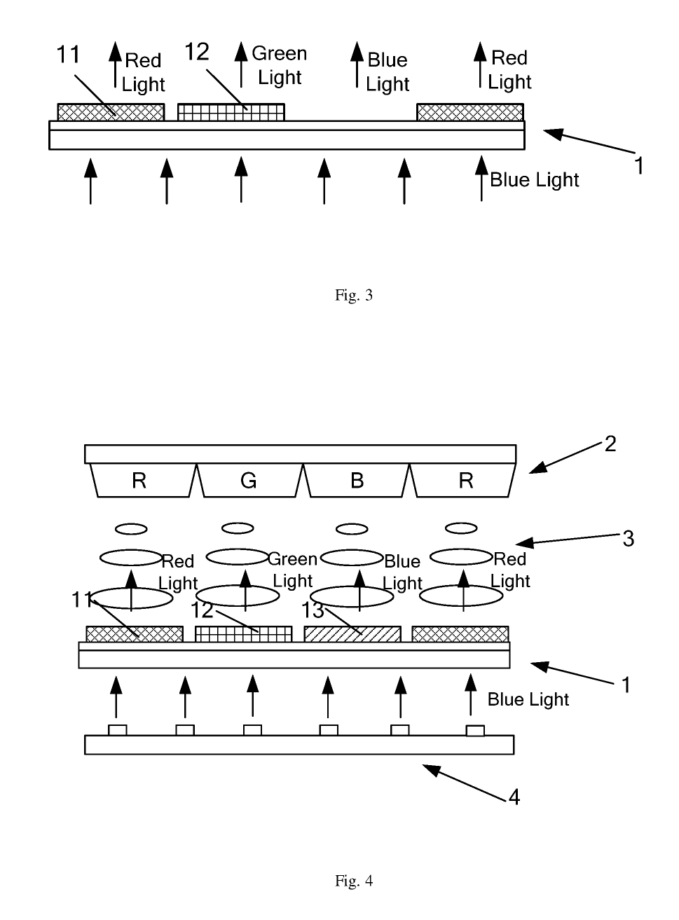

As another implementation of an embodiment of the present disclosure, as shown in FIG. 3, the blue light emitting unit of the array substrate 1 may be not provided therein with any blue phosphor layer, and since the backlight module 4 emits blue light, the blue light source may be directly transmitted through the blue light emitting unit, thereby saving cost.

In an embodiment of the present disclosure, the red light emitting unit, the green light emitting unit and the blue light emitting unit may be provided on a light incidence side of the array substrate 1 (for example, on a light incidence surface of the array substrate), or they may be provided on a light emergence side of the array substrate 1 (for example, on a light emergence surface of the array substrate). For example, the red light emitting unit, the green light emitting unit and the blue light emitting unit are provided on the light emergence side of the array substrate 1, such that the blue light source is spaced apart from the red light emitting unit, the green light emitting unit and the blue light emitting unit by a distance, thereby enabling a higher utilization rate of the blue light.

The array substrate 1 according to an embodiment of the present disclosure may be a COA substrate; that is, a color filter layer is also provided on the light emergence side of the array substrate 1. Here, it is noted that when the red light emitting unit, the green light emitting unit and the blue light emitting unit are provided on the light emergence side of the array substrate 1, color filters are provided on light emergence sides of the red light emitting unit, the green light emitting unit and the blue light emitting unit, that is, the red light emitting unit, the green light emitting unit and the blue light emitting unit are arranged between the array substrate 1 and the color filters.

Of course, the array substrate 1 according to another embodiment of the present disclosure may be a normal array substrate, the array substrate 1 and a color filter substrate 2 are assembled into a cell, with liquid crystal molecules filled between the array substrate 1 and the color filter substrate 2, and then the cell is packaged to form a liquid crystal panel. In this case, the red light emitting unit, the green light emitting unit and the blue light emitting unit on the array substrate 1 are arranged opposite to the red, green and blue filters on the color filter substrate 2 in one-to-one correspondence.

As described above, in the array substrate 1 according to embodiments of the present disclosure, when the blue backlight module 4 is used, the red phosphor layer, the green phosphor layer and the blue phosphor layer are provided on the array substrate 1, such that blue light emitted from the blue backlight module 4 is irradiated onto the red phosphor layer, the green phosphor layer and the blue phosphor layer on the array substrate 1 after having traveled through a distance, to excite them to emit red light, green light and blue light, which then is irradiated onto filters of corresponding colors. Alternatively, the array substrate 1 may be provided thereon with only the red phosphor layer and the green phosphor layer, such that red light and green light are obtained by exciting the phosphor layers with blue light emitted from the blue backlight module 4 and being irradiated onto the array substrate 1, and blue light is obtained by transmitting the blue light, which is emitted from the blue backlight module, through the blue light emitting unit, then the red light, the green light and the blue light are irradiated onto the filters of corresponding colors. As a result, transmittance and utilization rate of the light source can be improved.

An embodiment of the present disclosure further provides a method of manufacturing an array substrate 1, which may be the array substrate 1 described in the the above embodiments and comprises a red light emitting unit, a green light emitting unit and a blue light emitting unit, the blue light emitting unit being configured to, when being irradiated by blue light emitted from a light source, emit blue light; the method comprises steps of:

forming a red phosphor layer 11 in the red light emitting unit, the red phosphor layer 11 being configured for emitting red light under excitation of the blue light emitted from the light source; and

forming a green phosphor layer 12 in the green light emitting unit, the green phosphor layer 12 being configured for emitting green light under excitation of blue light.

In one embodiment, the method further comprises a step of: forming a blue phosphor layer 13 in the blue light emitting unit, the blue phosphor layer 13 being configured for, under excitation of the blue light emitted from the light source, emitting blue light.

Herein, it is noted that the red phosphor layer 11, the green phosphor layer 12 and the blue phosphor layer 13 may be formed on the array substrate 1 through an evaporation process, while a sequence of evaporating the red phosphor layer 11, the green phosphor layer 12 and the blue phosphor layer 13 is not limited.

In an embodiment of the present disclosure, the array substrate 1 may also be a COA substrate, that is, the method further comprises a step of forming color filters on a light emergence side of the array substrate 1. For example, this step particularly includes: forming a red filter, a green filter and a blue filter on the light emergence side of the array substrate 1; in an example, a mask used to form the red filter, the green filter and the blue filter is the same as a mask used to form the red phosphor layer 11, the green phosphor layer 12 and the blue phosphor layer 13. In this case, production cost may be saved.

Of course, the array substrate 1 may not be provided thereon with any color filter, and color filters may be provided on the color filter substrate 2; in this case, a mask used to form the red filter, the green filter and the blue filter on the color filter substrate 2 is the same as a mask used to form the red phosphor layer 11, the green phosphor layer 12 and the blue phosphor layer 13 on the array substrate 1, such that production cost may be saved and it can be ensured that the red phosphor layer 11, the green phosphor layer and the blue phosphor layer 13 on the array substrate 1 are arranged opposite to the red, green and blue filters on the color filter substrate 2 in one-to-one correspondence.

As shown in FIG. 4, an embodiment of the present disclosure provides a display device, comprises the array substrate 1 described in the above embodiments. In an example, the display device may further comprises an opposite substrate 2 arranged opposite to the array substrate 1, a liquid crystal layer 3 arranged between the substrates 1 and 2, and a backlight module 4. The substrate 2 may be a color filter substrate, which is provided with a red filter R, a green filter G and a blue filter B. The backlight module 4 may utilize a blue light source, such as a blue light LED.

In an embodiment of the present disclosure, the display device may be any product or component that has a display function, such as a liquid crystal display device or an electroluminescent display device, for example, a liquid crystal panel, an electronic paper, a mobile phone, a tablet computer, a television, a display, a notebook computer, a digital photo frame, a navigator or the like.

The display device according to embodiments of the present disclosure allows a better utilization rate of a light source.

It should be understood that the above embodiments are merely exemplary embodiments used for setting forth principles of the present disclosure and the present disclosure will not be limited to those. Various changes and modifications can be made by those skilled in the art without departing from principle and spirit of the present disclosure, and these changes and modifications also fall within the scopes of the present invention.

1. An array substrate, comprising a red light emitting unit, a green light emitting unit and a blue light emitting unit, wherein
the red light emitting unit comprises a red phosphor layer configured for emitting red light under excitation of blue light emitted from a light source;
the green light emitting unit comprises a green phosphor layer configured for emitting green light under excitation of the blue light emitted from the light source; and
the blue light emitting unit is configured for, when being irradiated by the blue light emitted from the light source, emitting blue light.

2. The array substrate according to claim 1, wherein the blue light emitting unit comprises a blue phosphor layer configured for, under excitation of the blue light emitted from the light source, emitting blue light.

3. The array substrate according to claim 2, wherein a material of the blue phosphor layer is BaMgAl₁₄O₂₃:Ru.

4. The array substrate according to claim 1, wherein the blue emitting light unit is configured to transmit the blue light, which is emitted from the light source and irradiated thereon, therethrough.

5. The array substrate according to claim 1, wherein the red light emitting unit, the green light emitting unit and the blue light emitting unit are provided on a light incidence side of the array substrate.

6. The array substrate according to claim 1, wherein the red light emitting unit, the green light emitting unit and the blue light emitting unit are provided on a light emergence side of the array substrate.

7. The array substrate according to claim 1, further comprising a color filter layer, wherein the color filter layer is arranged on light emergence sides of the red light emitting unit, the green light emitting unit and the blue light emitting unit.

8. The array substrate according to claim 1, wherein a material of the red phosphor layer is Y₂O₃:Ru, and a material of the green phosphor layer is SrGa₂S₄:Ru.

9. The array substrate according to claim 1, wherein the red light emitted by the red light emitting unit under excitation of the blue light emitted from the light source has a wavelength of 700±50 nm;
the green light emitted by the green light emitting unit under excitation of the blue light emitted from the light source has a wavelength of 546±50 nm; and
the blue light emitted by the blue light emitting unit when being irradiated by the blue light emitted from the light source has a wavelength of 435±50 nm.

10. A method of manufacturing an array substrate, wherein the array substrate comprises a red light emitting unit, a green light emitting unit and a blue light emitting unit, the blue light emitting unit being configured to, when being irradiated by blue light emitted from the light source, emit blue light, and
the method comprises steps of:
forming a red phosphor layer in the red light emitting unit, the red phosphor layer being configured for emitting red light under excitation of the blue light emitted from the light source; and
forming a green phosphor layer in the green light emitting unit, the green phosphor layer being configured for emitting green light under excitation of the blue light emitted from the light source.

11. The method according to claim 10, further comprising a step of:
forming a blue phosphor layer in the blue light emitting unit, the blue phosphor layer being configured for, under excitation of the blue light emitted from the light source, emitting blue light.

12. The method according to claim 11, further comprising a step of:
forming a color filter layer on light emergence sides of the red light emitting unit, the green light emitting unit and the blue light emitting unit.

13. The method according to claim 12, wherein the step of forming a color filter layer comprises:
forming a red filter, a green filter and a blue filter, and
wherein a mask used to form the red filter, the green filter and the blue filter is the same as a mask used to form the red phosphor layer, the green phosphor layer and the blue phosphor layer.

14. A display device, comprising the array substrate of claim 1.

15. The array substrate according to claim 2, further comprising a color filter layer, wherein the color filter layer is arranged on light emergence sides of the red light emitting unit, the green light emitting unit and the blue light emitting unit.

16. The array substrate according to claim 3, further comprising a color filter layer, wherein the color filter layer is arranged on light emergence sides of the red light emitting unit, the green light emitting unit and the blue light emitting unit.

17. The array substrate according to claim 4, further comprising a color filter layer, wherein the color filter layer is arranged on light emergence sides of the red light emitting unit, the green light emitting unit and the blue light emitting unit.

18. The array substrate according to claim 5, further comprising a color filter layer, wherein the color filter layer is arranged on light emergence sides of the red light emitting unit, the green light emitting unit and the blue light emitting unit.

19. The array substrate according to claim 6, further comprising a color filter layer, wherein the color filter layer is arranged on light emergence sides of the red light emitting unit, the green light emitting unit and the blue light emitting unit.

20. The display device according to claim 14, further comprising a color filter layer, wherein the color filter layer is arranged on light emergence sides of the red light emitting unit, the green light emitting unit and the blue light emitting unit so as to filter light from the red light emitting unit, the green light emitting unit and the blue light emitting unit.
